(19) United States
(12) Patent Application Publication
(10) Pub. No.: US 2013/0044415 A1
(43) Pub. Date: Feb. 21, 2013

(54) ELECTRONIC DEVICE

(71) Applicant: Cheng-Chao Peng, Taipei City (TW)

(72) Inventor: Cheng-Chao Peng, Taipei City (TW)

(73) Assignee: COMPAL ELECTRONICS, INC., Taipei City (TW)

(21) Appl. No.: 13/411,631

(22) Filed: Mar. 5, 2012

(30) Foreign Application Priority Data
Aug. 19, 2011 (TW) 100129780

(51) Int. Cl. H05K 5/00

(52) U.S. Cl. 361/679.01

(57) ABSTRACT

An electronic device including a first, a second and a third bodies and a positioning element is provided. The second body pivots to the first body. The third body pivots to the second body. The positioning element is slidably disposed in the second body. When an end of the positioning element moves to a position between the second body and a second pivot of the third body, rotation of the third body relative to the second body is limited.

### CROSS-REFERENCE TO RELATED APPLICATION

This application claims the priority benefit of Taiwan application serial no. 100129780, filed Aug. 19, 2011. The entirety of the above-mentioned patent application is hereby incorporated by reference herein and made a part of this specification.

### BACKGROUND OF THE INVENTION

1. Field of the Invention

The invention relates to an electronic device. Particularly, the invention relates to an electronic device having a folding case.

2. Description of Related Art

Along with development of semiconductor devices and display techniques, electronic devices are continually developed towards directions of miniaturization, multi-function and easy to carry. The commonly used portable electronic devices include personal digital assistants (PDAs), mobile phones and notebook computers, etc. A structure of the portable electronic device can be folded to reduce an occupation area, so as to achieve miniaturization of the electronic product. Taking the notebook computer as an example, it is generally consisted of a host and a display device pivotally connected to each other. The user can close the host and the display device of the notebook computer through relative pivot rotation there between to facilitate carrying around, and when the notebook computer is to be used, the display device is opened to facilitate operation.

### SUMMARY OF THE INVENTION

The invention is directed to an electronic device, in which pivot rotations of bodies are selectively limited, so as to improve operation convenience.

The invention provides an electronic device including a first body, a second body, a third body and at least one positioning element. The second body is pivoted to the first body through a first pivot. The third body is pivoted to the second body through a second pivot. The positioning element is slidably disposed in the second body. When an end of the positioning element moves to a position between the second body and the second pivot of the third body, rotation of the third body relative to the second body is limited.

In an embodiment of the invention, the first pivot has a first positioning hole, when another end of the positioning element is slidably disposed between the second body and the first pivot, the another end sticks into the first positioning hole to limit pivot rotation of the second body relative to the first body. In an embodiment of the invention, the second pivot of the electronic device has a second positioning hole, and the end of the positioning element sticks into the second positioning hole to limit pivot rotation of the third body relative to the second body. In an embodiment of the invention, a number of the at least one positioning element is two, and the two positioning elements are respectively disposed at two opposite sides of the second body and the third body.

In an embodiment of the invention, the electronic device further includes a linkage assembly including a first gear, a second gear and a transmission element. The first gear is meshed to one of the two positioning elements. The second gear is meshed to the other positioning element. The transmission element is connected between the first gear and the second gear. When one of the positioning element slides, it drives the first gear to rotate, and the first gear drives the second gear to rotate through the transmission element, so as to drive the other positioning element to slide relative to the second body along a same direction.

In an embodiment of the invention, the first body is a host, the second body is a display, and the third body is another display.

According to the above descriptions, when the third body of the invention is rotated to be coplanar with the second body, the positioning element is slidably disposed between the second body and the second pivot to limit the relative pivot rotation between the second body and the third body, so that when the user drives the second body to pivotally rotate relative to the first body, the second body is not pivotally rotated relative to the third body, so as to improve operation convenience.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of an electronic device according to a first embodiment of the invention.

FIG. 2 is a partial three-dimensional view of pivot rotation between a third body and a second body of FIG. 1.

FIG. 3 is a partial three-dimensional view of pivot rotation between a second body and a first body of FIG. 1.

FIG. 4 is a partial top view of the electronic device of FIG. 1.

### DETAILED DESCRIPTION OF DISCLOSED EMBODIMENTS

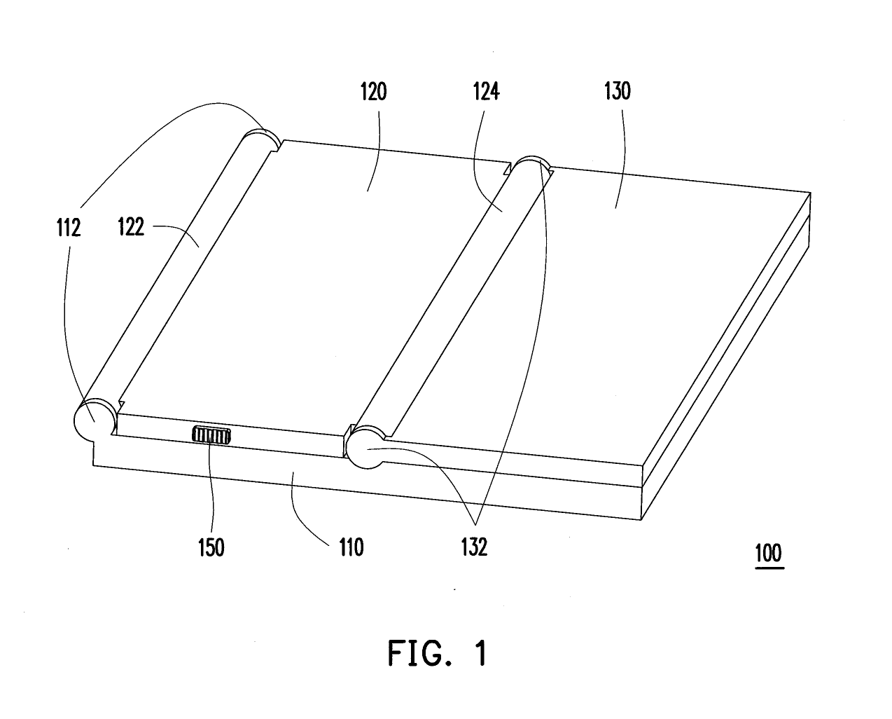

FIG. 1 is a three-dimensional view of an electronic device according to a first embodiment of the invention. Referring to FIG. 1, the electronic device 100 of the present embodiment includes a first body 110, a second body 120 and a third body 130. The first body 110 and the second body 120 are pivoted to each other, and the second body 120 and the third body 130 are pivoted to each other. The electronic device 100 is, for example, a notebook computer, the first body 110 is, for example, a host, and the second body 120 and the third body 130 are, for example, displays. Certainly, the invention is not limited thereto, and the first body, the second body and the third body can also be displays, or touch screens, etc.

Moreover, sizes of the first body 110, the second body 120 and the third body 130 are suitably designed, so that the second body 120 and the third body 130 are opportunely stacked on the first body 110. Certainly, the sizes of the first body 110, the second body 120 and the third body 130 can be changed according to an actual design requirement, and it is not limited to opportunely stack the second body 120 and the third body 130 on the first body 110.

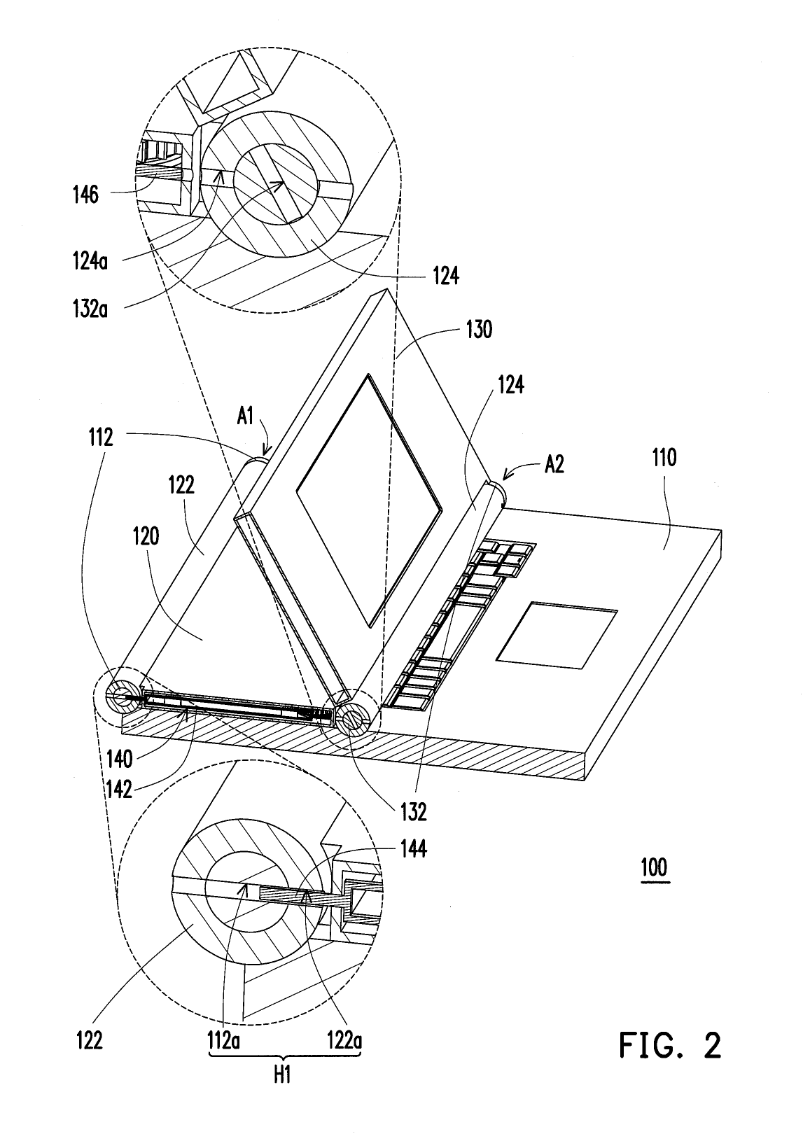

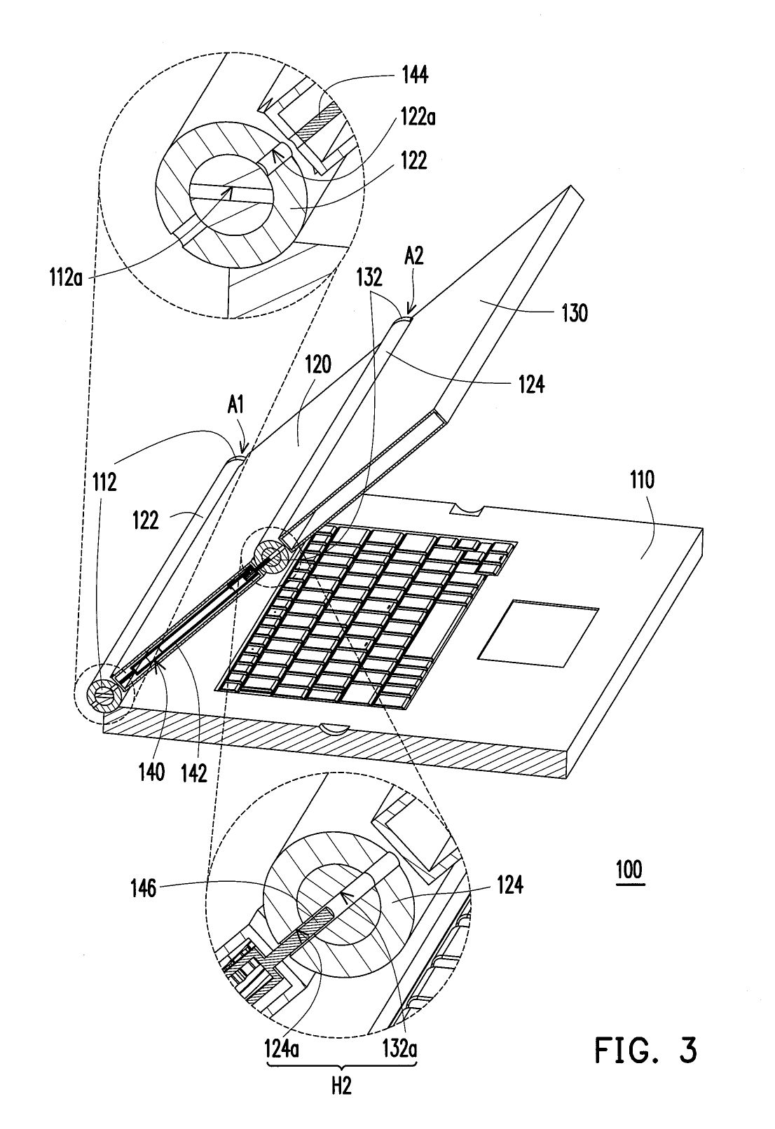

A structure and an actuation method of the electronic device 100 are described below with reference of FIG. 2 and FIG. 3.

Referring to FIG. 1 and FIG. 3, the first body 110 has a rotation shaft 112, and the rotation shaft 112 has a first through hole 112a. The second body 120 has a sleeve 122 and a sleeve 124. The sleeve 122 is pivoted to the rotation shaft 112 and has a second through hole 122a, and the sleeve 124 has a third through hole 124a. The third body 130 has a rotation shaft 132, and the rotation shaft 132 is pivoted to the sleeve 124 and has a fourth through hole 132a.

The rotation shaft 112 and the sleeve 122 form a first pivot A1, and the second body 120 is adapted to pivotally rotate relative to the first body 110 through the first pivot A1. The rotation shaft 132 and the sleeve 124 form a second pivot A2, and the third body 130 is adapted to pivotally rotate relative to the second body 120 through the second pivot A2.

The electronic device 100 of the embodiment further includes a positioning element 140.

As shown in FIG. 2, when the second body 120 is rotated to stack on the first body 110, one end of the positioning element 140 is slidably disposed between the second body 120 and the first pivot A1 to stop relative pivot rotation between the first body 110 and the second body 120. As shown in FIG. 3, when the third body 130 is rotated to be in a same plane with the second body 120, the positioning element 140 is slidably disposed between the second body 120 and the second pivot A2 to stop relative pivot rotation between the second body 120 and the third body 130. Besides, when the two ends of the positioning element 140 are all located in the second body 120, the positioning element 140 is not interfered with the first pivot A1 or the second pivot A2, so that the second body 120 can rotate relative to the first body 110 through the first pivot A1, and the third body 130 can rotate relative to the second body 120 through the second pivot A2.

In detail, when the sleeve 122 is pivotally rotated relative to the rotation shaft 112 to close the second body 120 to the first body 110 (for example, a state shown in FIG. 1 or FIG. 2), the second through hole 122a of the sleeve 122 is aligned to the first through hole 112a of the rotation shaft 112, and the second through hole 122a and the first through hole 112a form a first positioning hole H1. On the other hand, when the rotation shaft 132 is pivotally rotated relative to the sleeve 124, so that the third body 130 and the second body 120 are coplanar (for example, a state shown in FIG. 1 or FIG. 3), the fourth through hole 132a of the rotation shaft 132 is aligned to the third through hole 124a of the sleeve 124, and the fourth through hole 132a and the third through hole 124a form a second positioning hole H2. When the second through hole 122a is aligned to the first through hole 112a as that shown in FIG. 2, the positioning element 140 is adapted to slide towards the sleeve 122 to stick into the first positioning hole H1 formed by the first through hole 112a and the second through hole 122a as that shown in FIG. 2, so as to prevent relative rotation between the sleeve 122 and the rotation shaft 112. Moreover, when the fourth through hole 132a is aligned to the third through hole 124a as that shown in FIG. 3, the positioning element 140 is adapted to slide towards the sleeve 124 to stick into the second positioning hole H2 formed by the third through hole 124a and the fourth through hole 132a, so as to prevent relative rotation between the rotation shaft 132 and the sleeve 124.

In this way, when the second body 120 is closed to the first body 110 as that shown in FIG. 2, the user can drive the positioning element 140 to stick into the first positioning hole H1 formed by the first through hole 112a and the second through hole 122a, so as to limit the relative pivot rotation between the first body 110 and the second body 120, so that when the user drives the third body 130 to pivotally rotate relative to the second body 120, the second body 120 is not pivotally rotated relative to the first body 110. On the other hand, when the third body 130 and the second body 120 are coplanar as that shown in FIG. 3, the user can drive the positioning element 140 to stick into the second positioning hole H2 formed by the third through hole 124a and the fourth through hole 132a, so as to limit the relative pivot rotation between the second body 120 and the third body 130, so that when the user drives the third body 130 to pivotally rotate relative to the first body 110, the second body 120 is not pivotally rotated relative to the third body 130, so as to improve operation convenience.

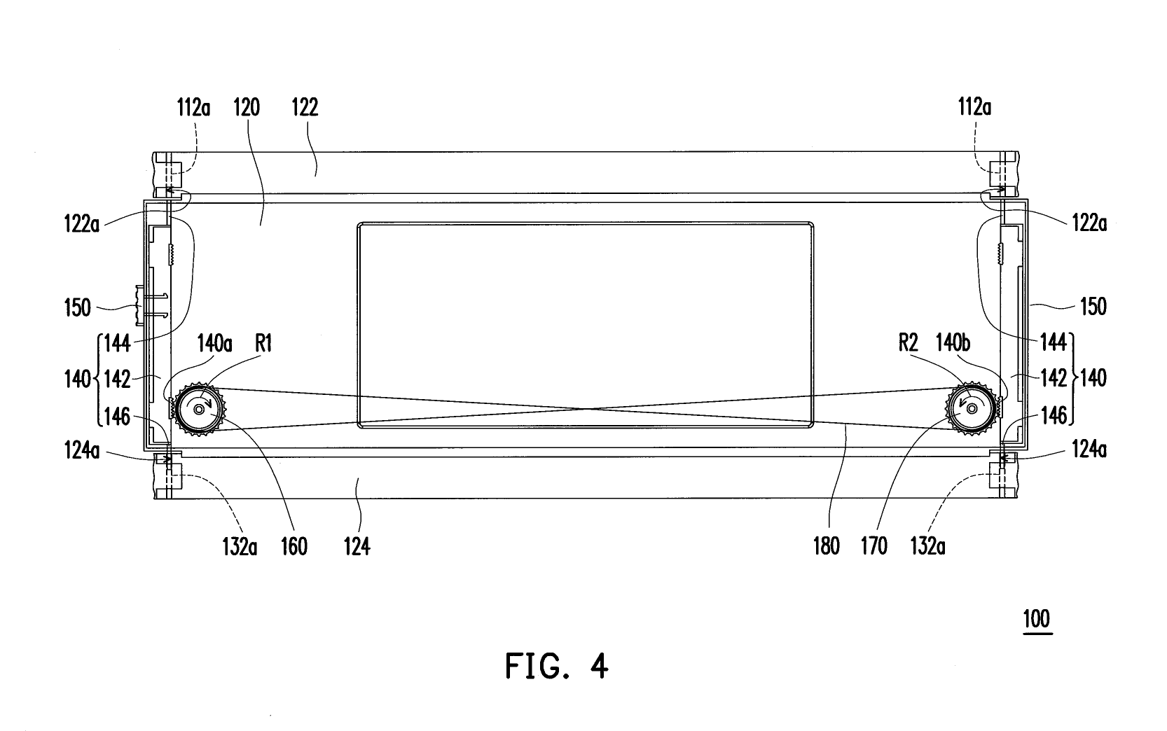

Referring to FIG. 1 and FIG. 4, in the present embodiment, the electronic device 100 further includes a key body 150. The key body 150 is connected to the positioning element 140 and is exposed outside the second body 120. The user can push the key body 150 to drive the positioning element 140 to slide towards the first pivot A1 or slide towards the second pivot A2.

Moreover, in the present embodiment, the positioning element 140 includes a sliding portion 142, a first positioning portion 144 and a second positioning portion 146. The sliding portion 142 is slidably disposed in the second body 120. The first positioning portion 144 is connected to the sliding portion 142 at an end facing to the sleeve 122, and is adapted to stick into the first positioning hole H1 formed by the first through hole 112a and the second through hole 122a as the sliding portion 142 slides relative to the second body 120. The second positioning portion 146 is connected to the sliding portion 142 at an end facing to the sleeve 124, and is adapted to stick into the second positioning hole H2 formed by the third through hole 124a and the fourth through hole 132a as the sliding portion 142 slides relative to the second body 120.

The number of the sliding element 140 is not limited by the invention, and in the present embodiment, two positioning elements 140 are disposed in the second body 120, and the two positioning elements 140 are respectively disposed at two opposite sides of the second body 120 and the third body 130, and the numbers of the first through hole 112a, the second through hole 122a, the third through hole 124a and the fourth through hole 132a are all two. When the sleeve 124 is pivotally rotated relative to the rotation shaft 112 to close the second body 120 to the first body 110 (shown in FIG. 1 or FIG. 2), the two second through holes 122a are respectively aligned to the two first through holes 112a. When the rotation shaft 132 is pivotally rotated relative to the sleeve 124 so that the third body 130 and the second body are coplanar (shown in FIG. 1 or FIG. 3), the two fourth through holes 132a are respectively aligned to the two third through holes 124a. When the two second through holes 122a are respectively aligned to the two first through holes 112a, the positioning elements 140 are adapted to slide towards the sleeve 122 to stick into the corresponding first through holes 112a and the corresponding second through holes 122a to prevent the sleeve 124 from pivotally rotating relative to the rotation shaft 122. When the two fourth through holes 132a are respectively aligned to the two third through holes 124a, the positioning elements 140 are adapted to slide towards the sleeve 124 to stick into the corresponding third through holes 124a and the corresponding fourth through holes 132a to prevent the rotation shaft 132 from pivotally rotating relative to the sleeve 124.

As shown in FIG. 4, in the present embodiment, the electronic device 100 further includes a linkage assembly, and the linkage assembly includes a first gear 160, a second gear 170 and a transmission element 180. The first gear 160 and the second gear 170 are disposed in the second body 120. One positioning element 140 has a first gear rack 140a, and another positioning element 140 has a second gear rack 140b. The first gear 160 and the second gear 170 are respectively meshed to the first gear rack 140a and the second gear rack 140b. The transmission element 180 is, for example, a belt, and is winded between the first gear 160 and the second gear 170. When the first positioning element 140 having the first gear rack 140a slides relative to the second body 120, the first gear rack 140a drives the first gear 160 to rotate, and the first gear 160 drives the second gear 170 to rotate through the transmission element 180, and the other positioning element 140 is driven by the second gear 170 through the second gear rack 140b to slide relative to the second body 120. In other words, based on the linkage of the first gear rack 140a, the first gear 160, the transmission element 180, the second gear 170 and the second gear rack 140b, as long as the user pushes the key body 150, the two positioning elements 150 can be driven to slide, simultaneously.

In detail, the first gear 160 and the second gear 170 are disposed between the first gear rack 140a and the second gear rack 140b. When the first gear 160 is rotated along a first rotation direction R1, the first gear 160 is adapted to drive the second gear 170 to rotate along a second rotation direction R2 opposite to the first rotation direction R1 through the transmission element 180, so as to drive the two positioning elements 150 to slide along a same direction. For example, the transmission element 180 (the belt) is configured in a cross manner as that shown in FIG. 4, so as to achieve the effect that the first gear 160 and the second gear 170 are respectively rotated along opposite directions.

In summary, when the second body is closed to the first body, the first through hole of the sleeve of the second body is aligned to the second through hole of the rotation shaft of the first body, so that the positioning element is adapted to stick into the first positioning hole formed by the first through hole and the second through hole, so as to limit the relative rotation between the first body and the second body, and when the user drives the third body to pivotally rotate relative to the second body, the second body is not pivotally rotated relative to the first body. On the other hand, when the third body and the second body are coplanar, the third through hole of another sleeve of the second body is aligned to the fourth through hole of the rotation shaft of the third body, so that the positioning element is adapted to stick into the second positioning hole formed by the third through hole and the fourth through hole, so as to limit the relative rotation between the second body and the third body, and when the user drives the second body to pivotally rotate relative to the first body, the second body is not pivotally rotated relative to the third body, so as to improve the operation convenience.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device, comprising:
a first body;
a second body, pivoted to the first body through a first pivot;
a third body, pivoted to the second body through a second pivot; and
at least one positioning element, slidably disposed in the second body, wherein when an end of the positioning element moves to a position between the second body and the second pivot, rotation of the third body relative to the second body is limited.

2. The electronic device as claimed in claim 1, wherein the first pivot has a first positioning hole, and when another end of the positioning element is slidably disposed between the second body and the first pivot, the another end sticks into the first positioning hole to limit pivot rotation of the second body relative to the first body.

3. The electronic device as claimed in claim 1, wherein the second pivot has a second positioning hole, and the end of the positioning element sticks into the second positioning hole to limit pivot rotation of the third body relative to the second body.

4. The electronic device as claimed in claim 1, wherein a number of the at least one positioning element is two, and the two positioning elements are respectively disposed at two opposite sides of the second body and the third body.

5. The electronic device as claimed in claim 4, further comprising a linkage assembly, comprising:
a first gear, meshed to one of the two positioning elements;
a second gear, meshed to the other positioning element; and
a transmission element, connected between the first gear and the second gear,
wherein when one of the positioning element slides to drive the first gear to rotate, the first gear drives the second gear to rotate through the transmission element, so as to drive the other positioning element to slide relative to the second body along a same direction.

6. The electronic device as claimed in claim 1, wherein when the two ends of the positioning element are all located in the second body, the second body rotates relative to the first body through the first pivot, and the third body rotates relative to the second body through the second pivot.
